(19) United States
(12) Patent Application Publication
(10) Pub. No.: US 2012/0021357 A1
(43) Pub. Date: Jan. 26, 2012

(54) POSITIVE-TYPE PHOTOSENSITIVE INSULATING RESIN COMPOSITION, AND PATTERN FORMING METHOD USING SAME

(75) Inventors: Katsumi Maeda, Tokyo (JP); Shintaro Yamamichi, Tokyo (JP)

(73) Assignee: NEC CORPORATION, Tokyo (JP)

(21) Appl. No.: 13/146,841

(22) PCT Filed: Jan. 29, 2010
(86) PCT No.: PCT/JP2010/000537

§ 371 Date: Oct. 11, 2011

(30) Foreign Application Priority Data
Jan. 29, 2009 (JP) 2009-018193

(51) Int. Cl. G03F 7/20; G03F 7/028

(52) U.S. Cl. 430/283.1; 430/325; 430/326

(57) ABSTRACT

A photosensitive insulating resin composition, comprising a polymer, a photosensitizer, and an amide derivative that is expressed by the following general formula (1);

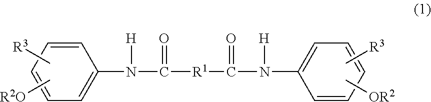

(in formula (1), R¹ represents a bivalent alkyl group, R² represents a hydrocarbon group with a carbon number of 1 to 10, and R³ represents a hydrogen atom or an alkyl group with a carbon number of 1 to 4.)

### TECHNICAL FIELD

The present invention relates to a photosensitive insulating resin composition, and a pattern forming method, and particularly to a positive-type photosensitive resin composition that can be applied to interlayer insulating film, surface protecting film and the like of semiconductor devices, and a pattern forming method.

Priority is claimed on Japanese Patent Application No. 2009-018193 filed Jan. 29, 2009, the content of which is incorporated herein by reference.

### BACKGROUND ART

Previously, polyimide resin with excellent film properties such as heat resistance, mechanical properties and electrical properties has been used in the interlayer insulating film and surface protecting film of semiconductor devices. However, when using non-photosensitive polyimide resin as interlayer insulating film or the like, it is necessary to additionally conduct operations that use a positive-type resist such as etching and resist removal in the pattern forming process, thereby complicating the manufacturing process. Consequently, studies have been conducted with respect to photosensitive polyimide resin having excellent photosensitivity. As such a photosensitive polyimide resin composition, one may cite the positive-type photosensitive resin composition containing a polyamide acid, aromatic bisazide compound, and amine compound disclosed in Patent Document 1. However, in the developing step of the pattern forming process of the photosensitive polyimide resin, it is necessary to have an organic solvent such as N-methyl-2-pyrrolidone or ethanol. Consequently, it is problematic in terms of safety and environmental effects.

Thus, in recent years, a positive-type photosensitive resin composition has been developed as a pattern forming material which enables development using an aqueous alkali solution such as an aqueous solution of tetramethylammonium hydroxide (TMAH) that is employed in the micropattern forming process of semiconductors. For example, in Patent Document 2, a positive-type photosensitive resin composition of the non-chemical amplification type is reported which contains a polybenzoxazole precursor and a diazoquinone compound which is a photosensitive agent. In Non-Patent Document 1, a positive-type photosensitive resin composition of the non-chemical amplification type is reported which contains a polybenzoxazole precursor and 1,2-naphthoquinone diazide-5-sulfonic acid ester. Moreover, in Non-Patent Document 2, a positive-type photosensitive resin composition of the chemical amplification type is reported which contains a polybenzoxazole precursor protected by an acid-degradable group and a photo-acid generator.

The structure of such photosensitive insulating resin composition changes due to heat treatment, forming benzoxazole rings. Consequently, a substance with excellent heat resistance and electrical properties is obtained. For example, with respect to the polybenzoxazole precursor disclosed in Non-Patent Document 1, benzoxazole rings are formed by heat treatment after alkali development, as shown in reaction formula A1 and reaction formula A2 recorded below. As benzoxazole rings have a stable structure, interlayer insulating film or surface protecting film which uses a photosensitive composition containing this polybenzoxazole precursor is film with excellent film properties such as heat resistance, mechanical properties and electrical properties.

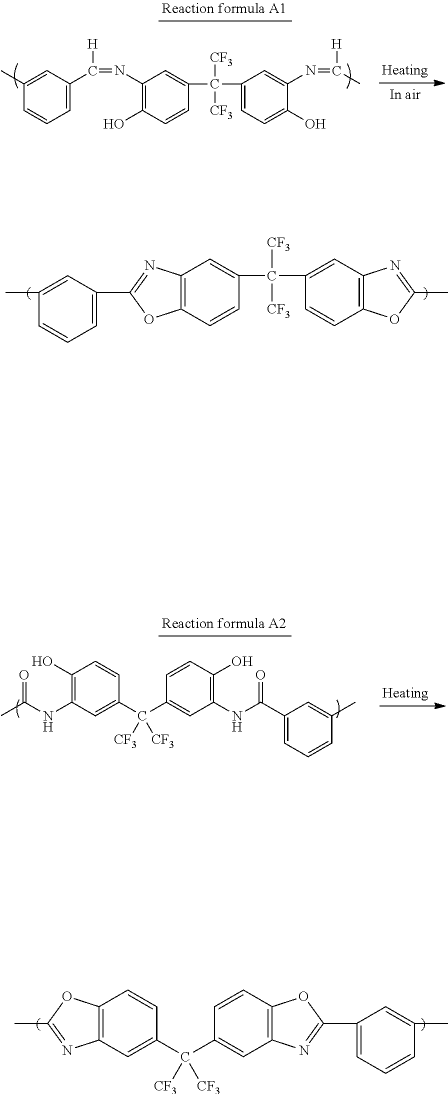

Otherwise, in the field of semiconductor device manufacturing, demands have grown in recent years for devices of ever higher density and integration, miniaturization of wiring patterns, and so on. In conjunction with this, requirements with respect particularly to photosensitive insulating resin composition used in interlayer insulating film, surface protecting film and the like have grown increasingly severe. However, the positive-type photosensitive resin compositions recorded in the respective documents mentioned above have not been fully satisfactory from the standpoint of resolution. As factors preventing excellent resolution, one may cite low contrast, and the failure of the resin micropatterns that are formed to fully adhere to the substrate.

As explained above, development of a photosensitive insulating resin composition is anticipated which, while maintaining previous film properties, also enables alkali development, obtains high-resolution, and further has excellent substrate adhesion properties such that the resin micropatterns that are formed do not easily peel off from the substrate.

### BACKGROUND ART LITERATURE

(Patent Documents)
Patent Document 1: Japanese Examined Patent Application Publication No. H3-36861
Patent Document 1: Japanese Examined Patent Application Publication No. H1-46862

(Non-Patent Documents)
Non-Patent Document 1: M. Ueda et al., Journal of Photopolymer Science and Technology, Vol. 16, No. 2, pp. 237-242 (2003)
Non-Patent Document 2: K. Ebara et al., Journal of Photopolymer Science and Technology, Vol. 16, No. 2, pp. 287-292 (2003)

### DISCLOSURE OF INVENTION

### Problems that the Invention is to Solve

The present invention was made in order to solve the aforementioned problems, and its first object is to offer a photosensitive insulating resin composition which has excellent film properties such as heat resistance, mechanical properties and electrical properties, which enables alkali development, which obtains high-resolution, and which has excellent substrate adhesion properties of the resin patterns that are formed. Moreover, a second object of the present invention is to offer a pattern forming method which uses the photosensitive insulating resin composition.

### Means for Solving the Problems

As a result of study aimed at achieving the aforementioned objectives, the present inventors discovered that a photosensitive insulating resin composition that also includes an amide derivative of specified structure in a photosensitive insulating resin composition containing a polymer and a photosensitizer enables development with an aqueous alkali solution, obtains high-resolution, and also has excellent adhesion to the substrate.

That is, a first aspect of the present invention is a photosensitive insulating resin composition which includes a polymer, a photosensitizer, and an amide derivative that is expressed by the following general formula (1).

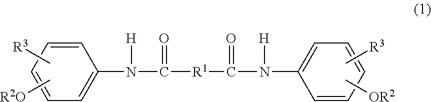

(In formula (1), R¹ represents a bivalent alkyl group, R² represents a hydrocarbon group with a carbon number of 1 to 10, and R³ represents a hydrogen atom or an alkyl group with a carbon number of 1 to 4.)

Moreover, with respect to the present invention, it is preferable that the aforementioned polymer be a polymer that contains one or more types of the repeating structural unit represented by general formula (2).

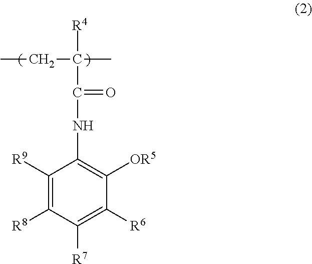

(In formula (2), R⁴ represents a hydrogen atom or a methyl group, R⁵ represents a hydrogen atom, or a group that is degraded (decomposed) by acid, and R⁶ to R⁹ each independently represent a hydrogen atom, a halogen atom, or an alkyl group with a carbon number of 1 to 4.)

Furthermore, with respect to the present invention, it is preferable that the aforementioned polymer be an alkali-soluble polymer, and that this polymer be a polymer that contains one or more types of the repeating structural unit represented by general formula (2) and one or more types of the repeating structural unit represented by the following general formula (3).

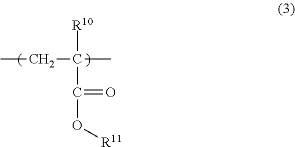

(In formula (3), R¹⁰ represents a hydrogen atom or a methyl group, and R¹¹ represents an organic group with a lactone structure.)

Furthermore, it is preferable that the present invention include a dissolution inhibitor.

It is preferable that the aforementioned dissolution inhibitor be a compound represented by the following general formula (4) or the following general formula (5).

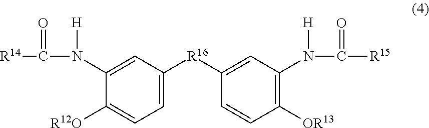

(In formula (4), R¹² and R¹³ represent groups that are degraded by acid, R¹⁴ and R¹⁵ represent straight-chain, branched or cyclic alkyl groups with a carbon number of 1 to 10, or aromatic hydrocarbon groups, and R¹⁶ represents a direct bond, —C(CF₃)₂—, —SO₂—, —CO—, —O— or bivalent hydrocarbon group.)

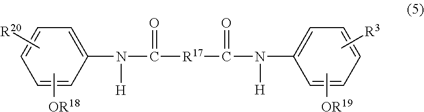

(In formula (5), R¹⁷ represents a bivalent hydrocarbon group, R¹⁸ and R¹⁹ represent groups that are degraded by acid, and R²⁰ and R²¹ represent hydrogen atoms, halogen atoms, or alkyl groups with a carbon number of 1 to 4.)

Furthermore, a second aspect of the present invention is a pattern forming method which at least includes the following steps:

a step in which any one of the aforementioned photosensitive insulating resin compositions is coated onto a workpiece substrate;

a step in which prebaking of the composition is conducted;

a step in which exposure of the composition is conducted;

a step in which post-exposure baking of the composition is conducted;

a step in which developing of the composition is conducted;

and a step in which post-baking of the composition is conducted.

In addition, it is preferable that the present invention additionally have a post-exposure step between the step in which developing is conducted and the step in which post-baking is conducted.

### Effects of the Invention

With the photosensitive insulating resin composition and pattern forming method of the present invention, it is possible to form a high-resolution pattern by development using an alkali developing solution. With heat treatment or heat treatment with an appropriate catalyst, a film is obtained which has excellent heat resistance, mechanical properties, electrical properties and the like. As the amide derivative represented by general formula (1) is included, it is also possible to offer a film that has excellent substrate adhesion properties.

### BEST MODE FOR CARRYING OUT THE INVENTION

The photosensitive insulating resin composition and pattern forming method of the present invention are described below.

<Photosensitive Insulating Resin Composition>

The photosensitive insulating resin composition of the present invention includes at least a polymer, a photosensitizer, and an amide derivative represented by the following general formula (1). Ordinarily, it is possible to prepare the composition by mixing the polymer, photosensitizer, and amide derivative.

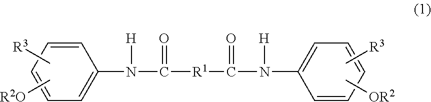

(In formula (1), R¹ represents a bivalent alkyl group, R² represents a hydrocarbon group with a carbon number of 1 to 10, and R³ represents a hydrogen atom or an alkyl group with a carbon number of 1 to 4.)

(Amide Derivative)

With respect to the amide derivative that is used in the photosensitive insulating resin composition of the present invention and that is represented by general formula (1), as the bivalent alkyl group indicated by R¹, one may cite as specific examples a methylene group, ethylene group, propylene group, butylene group, pentamethylene group, hexamethylene group, heptamethylene group, octamethylene group, decamethylene group and the like. As the hydrocarbon group with a carbon number of 1 to 10 indicated by R², one may cite a methyl group, ethyl group, propyl group, n-butyl group, phenyl group, naphtyl group and the like. As the alkyl group with a carbon number of 1 to 4 indicated by R³, one may cite a methyl group, ethyl group, n-propyl group, isopropyl group, n-butyl group, tert-butyl group and the like. As particularly preferable examples, there is a case where R¹ is an octamethylene group or butylene group, R² is a phenyl group or methyl group, and R³ is a hydrogen atom or methyl group.

The aforementioned amide derivative has an ether structure and an amide group of high polarity in the molecular structure. Consequently, by adding this amide derivative to the photosensitive insulating resin composition, adhesion to the substrate can be improved. In the case where the polymer has an amide skeleton, as it has an amide skeleton identical to that of the polymer, compatibility with the resin is also satisfactory, and a uniform photosensitive composition can, be made.

The manufacturing method of the aforementioned amide derivative can be selected as necessary. For example, it can be obtained by the reaction of dicarbonylchlorides and, aminophenols. For example, a method is disclosed in Japanese Unexamined Patent Application, First Publication No. H9-254540 in which synthesis is conducted by causing the reaction of phthalic acid dichlorides and aminophenols in a solvent of acetonitrile or tetrahydrofuran or the like in the presence of triethylamine.

With respect to the content of amide derivative, from the standpoint of achieving excellent substrate adhesion properties of the photosensitive insulating resin composition, it is preferable to have 0.5 mass % or more relative to the sum of the polymer and a photosensitizer such as a photo-acid generator, and 1 mass % or more is more preferable. On the other hand, from the standpoint of achieving satisfactory pattern formation, 25 mass % or less is preferable, and 15 mass % or less is more preferable. 2-10 mass % is particularly preferable.

As the amide derivative represented by general formula (1), one may cite the examples shown in Table 1, but one is not limited to these alone, and selection may be made as necessary.

TABLE 1
A-1

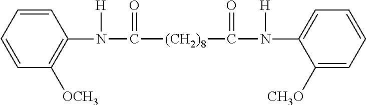

A-2

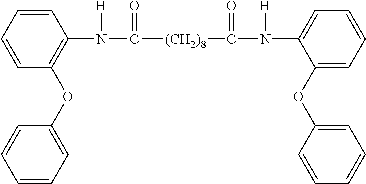

A-3

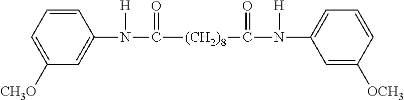

A-4

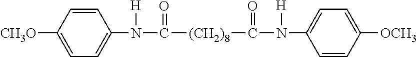

A-5

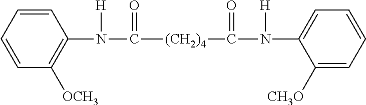

A-6

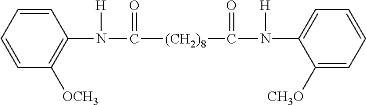

A-7

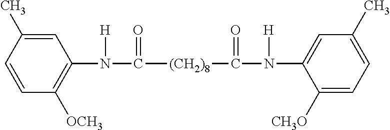

A-8

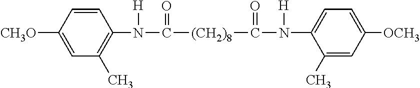

A-9

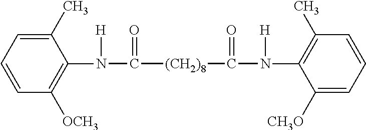

(Polymer)

The polymer used in the present invention may be selected according to necessity. As examples, one may cite polymers containing one or more types of repeating structural units represented by the following general formula (2), and the like.

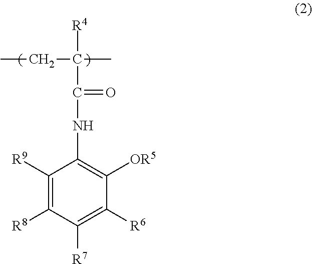

(In formula (2), R⁴ represents a hydrogen atom or a methyl group, R⁵ represents a hydrogen atom, or a group that is degraded by acid, and R⁶ to R⁹ each independently represent a hydrogen atom, a halogen atom, or an alkyl group with a carbon number of 1 to 4.)

With respect to the polymer used in the photosensitive insulating resin composition of the present invention represented by general formula (2), one may select as necessary a group that is degraded by acid denoted by R⁵. As examples, one may cite a t-butyl group, tetrahydropyran-2-yl group, tetrahydrofuran-2-yl group, 4-methoxytetrahydropyran-4-yl group, 1-ethoxyethyl group, 1-butoxyethyl group, 1-propoxyethyl group, methoxymethyl group, ethoxymethyl group, t-butoxycarbonyl group, and the like. It is preferable that R⁵ be an ethoxymethyl group, methoxymethyl group, or 1-ethoxyethyl group.

As the halogen atom denoted by R⁶ to R⁹, one may cite a fluorine atom, chlorine atom, and the like.

It is particularly preferable that R⁶ be a hydrogen atom or a methyl group. It is particularly preferable that R⁷ be a hydrogen atom or a methyl group. It is particularly preferable that R⁸ be a hydrogen atom or a methyl group. It is particularly preferable that R⁹ be a hydrogen atom or a methyl group.

As an alkyl group with a carbon number of 1 to 4 denoted by R⁶ to R⁹, one may cite a methyl group, ethyl group, n-propyl group, isopropyl group, n-butyl group, tert-butyl group, and the like.

As the repeating structural unit represented by general formula (2), one may cite the examples shown in Table 2, but one is not limited to these alone, and selection may be made as necessary. With respect to the proportion of the repeating structural unit represented by general formula (2) in the polymer, 10 to 100 is preferable, and 20 to 100 is more preferable.

TABLE 2
B-1

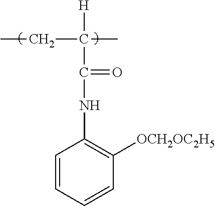

B-2

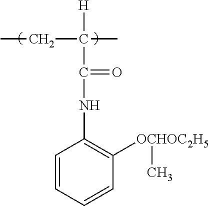

B-3

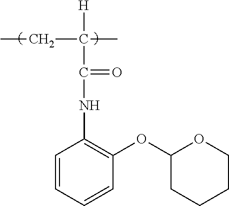

B-4

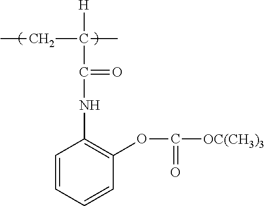

B-5

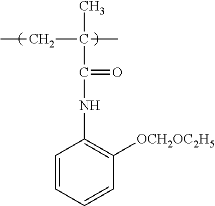

B-6

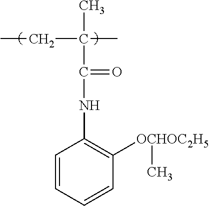

B-7

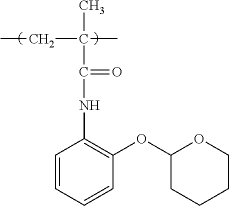

B-8

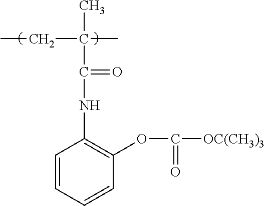

B-9

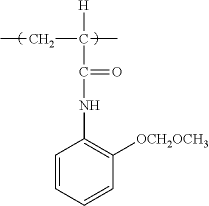

B-10

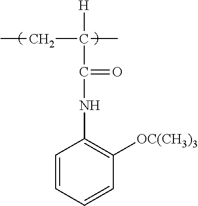

B11

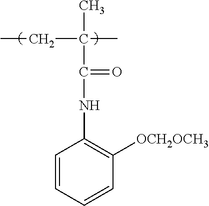

B-12

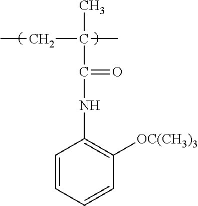

B-13

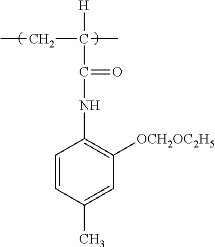

B-14

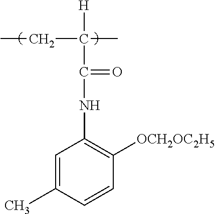

B-15

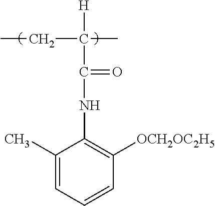

B-16

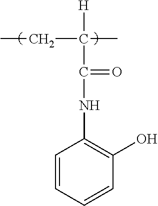

B-17

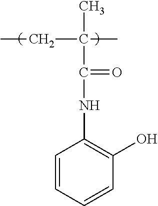

When the polymer used in the present invention undergoes heat treatment after forming a pattern, or when it undergoes heat treatment after an acid-degradable group is degraded by acid, a ring-closing reaction occurs, and imide rings or benzoxazole rings are formed. Accordingly, a film is obtained with excellent heat resistance, mechanical properties, electrical properties, and the like.

For example, with respect to the following acrylamide polymer wherein group A is an acid-degradable group, by conducting heat treatment, or by conducting heat treatment after the acid-degradable group is degraded by acid, a ring-closing reaction occurs, and a benzoxazole ring is formed, as shown in the following reaction formula B.

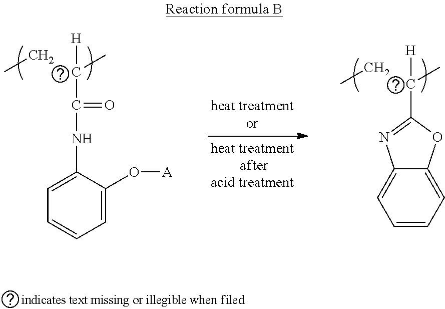

This benzoxazole ring has a stable structure. Consequently, by using this type of polymer in interlayer insulating film or surface protecting film, it is possible to form interlayer insulating film or surface protecting film that has excellent heat resistance, mechanical properties, electrical properties, and the like.

With respect to the polymer used in the present invention, there are no particular limitations on the raw material or method pertaining to the polymer containing a repeating structural unit represented by general formula (2) provided that such a polymer can be synthesized. For example, it is possible to suitably use as raw material the (metha)acrylamide derivative represented by general formula (6).

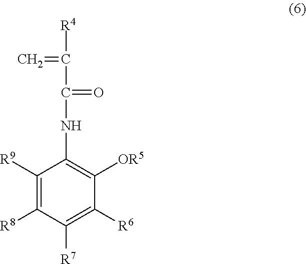

(In formula (6), R⁴ represents a hydrogen atom or a methyl group, R⁵ represents a hydrogen atom, or a group that is degraded by acid, and R⁶ to R⁹ each independently represent a hydrogen atom, a halogen atom, or an alkyl group with a carbon number of 1 to 4.)

The polymer containing a repeating structural unit represented by general formula (2) used in the present invention may, for example, be obtained by polymerizing the (metha)acrylamide derivative represented by general formula (6) alone. Or it may be a copolymer obtained by using the aforementioned (metha)acrylamide derivative as the principal monomer, and by copolymerizing this principal monomer and one or more other comonomers. In this instance, it is preferable that the proportion of the aforementioned (metha)acrylamide derivative relative to all monomers be 10 to 100, and 20 to 100 is more preferable. With respect to the copolymer obtained by copolymerization of the aforementioned (metha)acrylamide derivative and comonomers, the properties of the comonomers are added. Consequently, by using various comonomers, it is possible to enhance the properties that are useful to the photosensitive insulating resin composition containing this polymer (resolution and sensitivity) and the properties that are useful to the interlayer insulating film or surface protecting film formed by the photosensitive resin (e.g., heat resistance, mechanical properties, electrical properties, and the like). The form of the co-polymer may be selected as necessary. For example, a random copolymer, block copolymer, or graft copolymer is acceptable.

The comonomers may be selected as necessary. As examples of comonomers, vinyl monomers are preferable, because they are fully polymerizable with the aforementioned (metha)acrylamide derivative. As vinyl monomers, one may use, for example, (metha)acrylamide derivatives other than the aforementioned (metha)acrylamide derivative, butadiene, acrylonitrile, styrene, (metha)acrylic acid, (metha)acrylic acid ester derivatives, ethylene derivatives, styrene derivatives, and the like.

As ethylene derivatives, one may cite ethylene, propylene, vinyl chloride, and the like. As styrene derivatives, one may cite α-methylstyrene, p-hydroxystyrene, chlorostyrene, the styrene derivatives recorded in Japanese Unexamined Patent Application, First Publication No. 2001-172315, and the like.

In addition to vinyl monomers, one may use such comonomers as maleic acid anhydride and N-phenylmaleimide derivatives. As N-phenylmaleimide derivatives, one may use N-phenylmaleimide, N-(4-methylphenyl)maleimide, and the like. These comonomers may be used alone, or in two or more types.

With respect to the aforementioned copolymers, as specific examples of structural units obtained from comonomers, one may cite structural units derived from (metha)acrylic ester having a lactone ring represented by the following general formula (3).

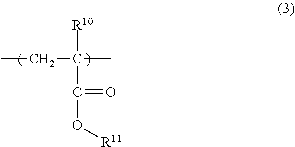

(In formula (3), R¹⁰ represents a hydrogen atom or a methyl group, and R¹¹ represents an organic group having a lactone structure.)

As the repeating structural unit represented by general formula (3), one may cite the examples of the following Table 3, but one is not limited to these alone.

TABLE 3
C-1

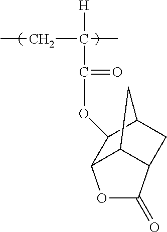

C-2

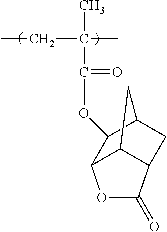

C-3

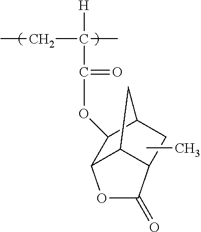

C-4

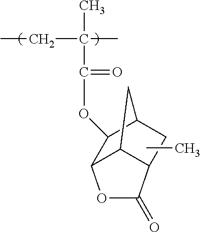

C-5

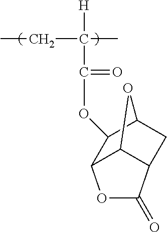

C-6

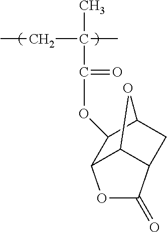

C-7

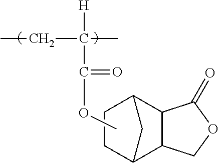

C-8

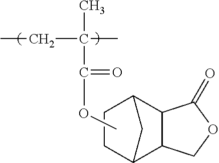

C-9

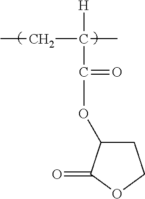

C-10

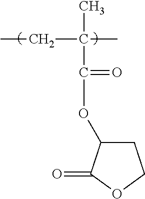

C-11

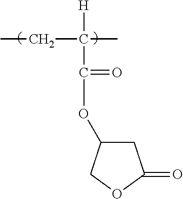

C-12

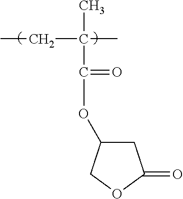

In the case where the photosensitive insulating resin composition of the present invention is used in interlayer insulating film or surface protecting film, in order to cause excellent film properties to be manifested by the polymer used in the present invention, it is preferable that the proportion in which the repeating structural unit represented by general formula (2) occurs in the polymer be 10-100 mol %; 20-100 mol % is more preferable; and 30-100 mol % is still more preferable.

As the weight-average molecular weight (Mw) of the polymer contained in the photosensitive insulating resin composition of the present invention, 2,000-200,000 is ordinarily preferable, and 4,000-100,000 is more preferable. In the case where the weight-average molecular weight (Mw) of the polymer is less than 2,000, when the polymer is used in interlayer insulating film or surface protecting film, it may be difficult to form the film uniformly. In the case where the weight-average molecular weight of the polymer exceeds 200,000, when the polymer is used in interlayer insulating film or surface protecting film, resolution may deteriorate.

The polymer containing a repeating structural unit represented by general formula (2) may, for example, be obtained by subjecting a monomer composition containing a (metha)acrylamide derivative like the ones mentioned above to polymerization by an ordinarily used polymerization method such as radical polymerization or anionic polymerization.

For example, in the case of radical polymerization, a monomer composition containing a (metha)acrylamide derivative represented by general formula (6) is dissolved in dry tetrahydrofuran, a radical polymerization initiator appropriate thereto such as 2,2′-azobis (isobutyronitrile) is added, after which the polymer is obtained by conducting stirring for 0.5 to 24 hours at 50-70° C. in an atmosphere of inert gas such as argon or nitrogen.

The polymer used in the present invention may have an acid-degradable group. In the case where the polymer used in the present invention has an acid-degradable group, it is desirable that the employed photosensitizer be a photo-acid generator which generates acid by optical irradiation with light which is used for exposure. There are no particular limitations on the photo-acid generator used in the present invention, provided that a mixture of the photo-acid generator and the polymer or the like of the present invention can be fully dissolved in an organic solvent, and provided that a uniform coating film can be formed by a film-forming method such as spin coating using that solution. Moreover, the photosensitizer may be used alone, or in a mixture of two or more types.

The photo-acid generator may be selected as necessary. As examples of a photo-acid generator, one may cite triaryl sulfonium salt derivative, diaryl iodonium salt derivative, dialkylphenacyl sulfonium salt derivative, nitrobenzyl sulfonate derivative, ester sulfonate derivatives of N-hydroxynaphthal imide, ester sulfonate derivatives of N-hydroxysuccinimide, and the like. However, one is not limited to these alone.

With respect to the content of the photo-acid generator or the photosensitizer, from the standpoints of achieving sufficient sensitivity of photosensitive resin compositions of the chemical amplification type, and enabling satisfactory pattern formation, 0.2 mass % or more relative to the sum of the polymer and the photo-acid generator or the photosensitizer is preferable, and 0.5 mass % or more is more preferable. On the other hand, from the standpoints of achieving formation of a uniform coating film, and inhibiting post-development residue (scum), 30 mass % or less is preferable, and 15 mass % or less is more preferable. 1 to 10 mass % is particularly preferable.

When pattern exposure is conducted by the below-mentioned actinic rays with respect to the photosensitive insulating resin composition of the present invention using a photo-acid generator, acid is generated from the photo-acid generator that composes the photosensitive insulating resin composition in the exposed portions, and reacts with the acid-degradable groups in the resin, and the acid-degradable groups undergo a degradation reaction. As a result, the polymer of the present invention changes from insoluble to soluble relative to the alkali developing solution in the exposed portions, and a disparity in solubility (solubility contrast) arises between the exposed portions and the unexposed portions. The pattern formation using this photosensitive insulating resin composition is conducted utilizing this disparity in solubility relative to alkali developing solution.

In the case where the photosensitive insulating resin composition is produced using a photo-acid generator and a polymer that does not contain an acid-degradable group (R⁵ is a hydrogen atom) as the polymer that contains a repeating structural unit represented by general formula (2)—that is, a polymer that does not sufficiently produce a disparity in solubility (solubility contrast) between the exposed portions and the unexposed portions—it is possible to create solubility contrast by, for example, incorporating a dissolution inhibitor having the below-mentioned acid-degradable group(s). In this case, when pattern exposure is conducted with the below-mentioned actinic rays, acid is generated from the photo-acid generator contained in the photosensitive insulating resin composition of the exposed portions, and reacts with the acid-degradable group in the dissolution inhibitor, with the result that the acid-degradable group in the dissolution inhibitor undergoes degradation reaction. As a result, dissolution is no longer blocked by the dissolution inhibitor in the exposed portions, and the resin composition of the present invention becomes soluble relative to the alkali developing solution in the exposed portions. On the other hand, insolubility with respect to the alkali developing solution in the unexposed portions remains unchanged. In this manner, a disparity in solubility (solubility contrast) arises between the exposed portions and the unexposed portions. Pattern formation using this type of photosensitive insulating resin composition is also conducted utilizing a disparity in solubility relative to alkali developing solution.

In the present invention, it is preferable to conduct use by combining a dissolution inhibitor with a polymer containing an acid-degradable group as the polymer containing a repeating structural unit represented by general formula (2).

When preparing the photosensitive insulating resin composition of the present invention, one may use a suitable solvent as necessary.

There are no particular limitations on the solvent provided that it fully dissolves the photosensitive insulating resin composition, and provided that it is an organic solvent or the like that enables uniform application of the solution by the spin coating method or the like. Specifically, one may use γ-butyrolactone, propylene glycol monomethylether acetate, propylene glycol monoethylether acetate, ethyl lactate, 2-heptanone, 2-methoxybutyl acetate, 2-ethoxyethyl acetate, methyl pyruvate, ethyl pyruvate, methyl 3-methoxypropionate, ethyl 3-methoxypropionate, N-methyl-2-pyrrolidone (NMP), cyclohexanone, cyclopentanone, methylisobutyl ketone (MIBK), ethylene glycol monomethyl ether, ethylene glycol monomethyl ether acetate, ethylene glycol monoethyl ether, ethylene glycol monoisopropyl ether, diethylene glycol monomethyl ether, diethylene glycol dimethyl ether, and the like. These may be used alone, or in a mixture of two or more types. In the case where the photosensitive insulating resin composition of the present invention is dissolved in a solvent for use, the proportion may be selected as necessary.

Furthermore, the photosensitive insulating resin composition may also be prepared by adding other components as necessary, such as dissolution promoters, dissolution inhibitors, adhesion enhancers, surfactants, pigments, stabilizers, coating enhancers, and dyes.

For example, by adding a dissolution inhibitor to the photosensitive insulating resin composition, dissolution of the unexposed portions of the photosensitive resin is inhibited relative to the alkali developing solution. On the other hand, in the exposed portions, the acid-degradable group that exists in the structure of the dissolution inhibitor is degraded by the action of the acid that is generated from the photo-acid generator, and solubility relative to the alkali developing solution increases. As a result, the solubility contrast of the unexposed portions and the exposed portions increases, enabling formation of a micropattern.

In the case where a dissolution inhibitor is added to the photosensitive insulating resin composition, from the standpoint of enabling satisfactory pattern formation of the photosensitive insulating resin composition, it is preferable to set its content at 1 mass % or more relative to the sum of the polymer, amide derivative and photo-acid generator, and 5 mass % or more is more preferable. On the other hand, in order to achieve formation of a uniform coating film, it is preferable to have 70 mass % or less, and 50 mass % or less is more preferable. 10 to 40 mass % is most preferable.

As specific examples of a dissolution inhibitor, one may cite the compounds represented by the following general formula (4) or the following general formula (5). However, one is not limited to these alone.

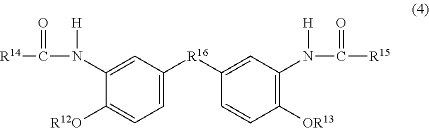

(In formula (4), R¹² and R¹³ represent groups that are degraded by acid, R¹⁴ and R¹⁵ represent straight-chain, branched or cyclic alkyl groups with a carbon number of 1 to 10, or aromatic hydrocarbon groups, and R¹⁶ represents a direct bond, —C(CF₃)₂—, —SO₂—, —CO—, —O— or bivalent hydrocarbon group.)

In formula (4), R¹² and R¹³ may be mutually identical or different, and are groups which are degraded by acid. They may be selected as necessary, and one may cite as specific examples a t-butyl group, tetrahydropyran-2-yl group, tetrahydrofuran-2-yl group, 4-methoxytetrahydropyran-4-yl group, 1-ethoxyethyl group, 1-butoxyethyl group, 1-propoxyethyl group, methoxymethyl group, ethoxymethyl group, or t-butoxycarbonyl group, or the like. The straight-chain, branched or cyclic alkyl group with a carbon number of 1 to 10 of R¹⁴ and R¹⁵ may be selected as necessary. As specific examples, one may cite a methyl group, ethyl group, butyl group, cyclohexyl group, norbornyl group, 5-norbornene-2-yl group, and the like. The aromatic hydrocarbon groups of R¹⁴ and R¹⁵ may be mutually identical or different, and may be selected as necessary. As specific examples, one may cite a phenyl group, tolyl group, naphtyl group, and the like. Furthermore, R¹⁶ is a directly bond, —C(CF₃)₂—, —SO₂—, —CO—, —O— or bivalent hydrocarbon group (as specific examples, one may cite —C(CH₃)₂—, —CH₂— adamantane-diyl group, tricyclodecane-diyl group, norbornane-diyl group, cyclohexane-diyl group, phenylene group, and the like).

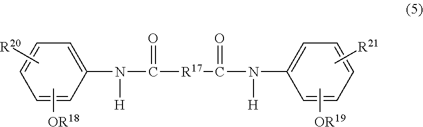

(In formula (5), R¹⁷ represents a bivalent hydrocarbon group, R¹⁸ and R¹⁹ represent groups that are degraded by acid, R²⁰ and R²¹ represent hydrogen atoms, halogen atoms, or alkyl groups with a carbon number of 1 to 4.)

The bivalent hydrocarbon group of R¹⁷ may be, selected as necessary. As specific examples, one may cite a phenylene group, naphthylene group, adamantine-diyl group, tricyclodecane-diyl group, norbornane-diyl-diyl group, cyclohexane-diyl group, and the like. The groups that are degraded by acid represented by R¹⁸ and R¹⁹ may be mutually identical or different, and may be selected as necessary. As specific examples, one may cite a t-butyl group, tetrahydropyran-2-yl group, tetrahydrofuran-2-yl group, 4-methoxytetrahydropyran-4-yl group, 1-ethoxyethyl group, 1-butoxyethyl group, 1-propoxyethyl group, methoxymethyl group, ethoxymethyl group, t-butoxycarbonyl group, and the like. R²⁰ and R²¹ may be mutually identical or different, and are hydrogen atoms, halogen atoms, or alkyl groups with a carbon number of 1 to 4. The alkyl groups may be selected as necessary, and one may cite as specific examples a methyl group, ethyl group, n-propyl group, isopropyl group, n-butyl group, tert-butyl group, and the like.

The photosensitive insulating resin composition of the present invention has excellent pattern resolution, enables developing treatment with alkali developing solution, and exhibits excellent adhesion of the formed pattern to the substrate. Moreover, film composed of the photosensitive insulating resin composition of the present invention has excellent film properties such as heat resistance, mechanical properties, electrical properties, and the like. Accordingly, this type of photosensitive insulating resin composition may be suitably used to form interlayer insulating film or surface protecting film. The photosensitive insulating resin composition of the present invention may be preferentially used as a positive-type photosensitive composition.

<Pattern Forming Method>

The pattern forming method of the present invention includes at least a coating step, a prebaking step, an exposure step, a post-exposure baking step, a developing step, and a post-baking step. More particularly, it includes at least in the following order: a coating step in which the aforementioned photosensitive insulating resin composition is coated onto a workpiece substrate; a prebaking step in which the aforementioned photosensitive insulating resin composition coating film is fixed to the workpiece substrate; an exposure step in which the aforementioned photosensitive insulating resin composition coating film is selectively exposed; a post-exposure baking step in which the photosensitive insulating resin composition coating film is baked after exposure; a developing step in which the exposed portions of the aforementioned photosensitive insulating resin composition coating film are dissolved and removed to form a pattern; and a post-baking step in which the photosensitive insulating resin composition coating film on which a pattern has been formed is hardened. Furthermore, with respect to the pattern forming method of the present invention, it is also acceptable to include a post-exposure step between the developing step and the post-baking step.

The coating step is a step in which the aforementioned photosensitive insulating resin composition is coated onto a workpiece substrate such as, for example, a silicon wafer, a ceramic substrate, or the like. The workpiece substrate may be selected as necessary. As the coating method, one may use a rotary coating method using spin coating, a spray coating method using a spray coater, an immersion method, a printing method, a roll coating method, or the like.

The prebaking step is a step in which the photosensitive insulating resin composition that has been coated onto the workpiece substrate is dried, and the solvent is removed, for purposes of fixing the photosensitive insulating resin composition coating film onto the workpiece substrate. It is ordinarily preferable to conduct the prebaking step at 60-150° C. The time period may be selected as necessary.

The exposure step is a step in which the photosensitive insulating resin composition coating film is selectively exposed via a photomask, producing exposed portions and unexposed portions, and transferring the pattern on the photomask to the photosensitive insulating resin composition coating film. The actinic rays used in pattern exposure may be selected as necessary. As the actinic rays that may be preferentially employed in the present invention, there are ultraviolet rays, visible light rays, excimer laser rays, electron rays, x-rays, and the like. Actinic rays with a wavelength of 180-500 nm may be more preferably employed.

The post-exposure baking step is a step in which the reaction of the acid-degradable groups of the polymer and the acid generated by exposure is accelerated. It is ordinarily preferable to conduct the post-exposure baking step at 60-150° C. The time period may be selected as necessary.

The developing step is a step in which the exposed portions of the photosensitive insulating resin composition coating film are dissolved and removed with alkali developing solution to form a pattern. Due to the aforementioned exposure step, a disparity in solubility (solubility contrast) has been produced between the polymer in the exposed portions and the unexposed portions of the photosensitive insulating resin composition coating film relative to the alkali developing solution. By utilizing this solubility contrast, the exposed portions of the photosensitive insulating resin composition coating film are dissolved and removed by the alkali developing solution, and a photosensitive insulating resin composition coating film in which a pattern has been formed (hereinafter simply “pattern”) is obtained. The alkali developing solution may be selected as necessary, and one may use aqueous solutions of quaternary ammonium base such as tetramethyalammonium hydroxide (TMAH) and tetraethylammonium hydroxide, and also water-soluble alcohols such as methanol and ethanol, and aqueous solutions to which surfactants and the like have been added in suitable amounts. The developing method may be selected as necessary, and methods such as puddling, immersion, and spraying are possible. After the developing step, it is preferable to rinse the formed pattern with water.

The post-baking step is a step in which heat treatment is conducted with respect to the obtained pattern under an air or inert gas atmosphere such as a nitrogen atmosphere, adhesion of the pattern and the workpiece substrate is increased, and the pattern is hardened. By heating the pattern formed by the photosensitive insulating resin composition in this post-baking step, the structure of the polymer composing the photosensitive insulating resin composition is changed (denatured), benzoxazole rings are formed, and the pattern is hardened. In this manner, it is possible to obtain a pattern with excellent film properties such as heat resistance, mechanical properties, electrical properties, and the like. The post-baking step is ordinarily conducted at 100-380° C., and heating within that range is also preferable in the present invention. 180-280° C. is more preferable. The post-baking step may be conducted in a single stage or in multiple stages. The time period may be selected as necessary, but 0.5-3 hours is preferable, and 0.5-2 hours is more preferable. It is preferable to conduct post-baking at a higher temperature than pre-baking.

The post-exposure step which may be conducted between the step in which developing is conducted and the step in which post-baking is conducted is a step in which the photosensitive insulating resin composition coating film in which a pattern has been formed is further exposed over its entire surface, accelerating hardening of the pattern in the subsequent post-baking process. According to conditions, it is also possible to conduct photobreaching (photodegradation) of the residual photosensitizer. As the actinic rays used in post-exposure, one may use the same actinic rays employed in the aforementioned exposure step, and actinic rays with a wavelength of 180-500 nm are preferable.

### EXAMPLES

The present invention is described in further detail below with reference to examples.

### Synthetic Example 1

Synthesis of an amide derivative (A-1 in Table 1) wherein R¹ is an octamethylene group, R² is a methyl group, and R³ is a hydrogen atom in general formula (1)

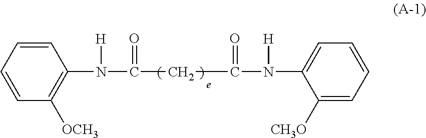

27.5 g of o-anisidine and 30.24 g of N,N-diisopropylethyl amine were dissolved in 200 ml of N-methyl-2-pyrrolidone (NMP). 25.43 g of sebacoyl chloride was gradually added to this, while the container including the mixture was stored in ice. After stirring for two hours under said cooling condition, it was stirred overnight at room temperature. Subsequently, the reaction mixture was poured into 1500 ml of water, the precipitate that was deposited was filtered, and then washed with water. After reduced-pressure drying, it was washed with diethyl ether, and further subjected to ethyl acetate/tetrahydrofuran (2/1) recrystallization, whereby 25.52 g of the white target substance was obtained (58% yield).

### Synthetic Example 2

Synthesis of an amide derivative (A-2 in Table 1) wherein R¹ is an octamethylene group, R² is a phenyl group, and R³ is a hydrogen atom in general formula (1)

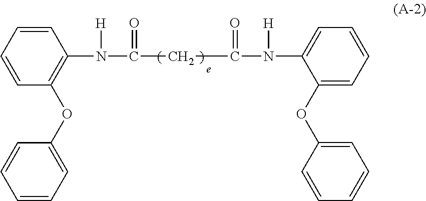

Synthesis was conducted in a manner identical to synthetic example 1, except that 2-phenoxyaniline was used instead of o-anisidine to obtain the white target substance (47% yield).

### Synthetic Example 3

Synthesis of a polymer containing 50 mol % of a structural unit (B-16 in Table 2) wherein R⁴-R⁹ are hydrogen in general formula (2), and 50 mol % of a structural unit (B-1 in Table 2) wherein R⁴ is a hydrogen atom, R⁵ is an ethoxymethyl group, and R⁶-R⁹ are hydrogen atoms in general formula (2) (numerals assigned below to repeating units indicate mol %)

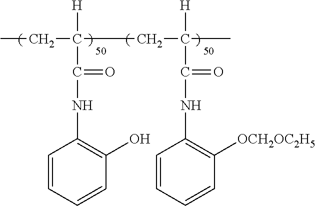

12.2 g of N-(2-hydroxyphenyl)acrylamide and 9 g of N-(2-ethoxymethoxyphenyl)acrylamide were dissolved in 50 ml of tetrahydrofuran. 0.181 g of 2,2′-azobis(isobutyronitrile) was added to that, and heating and stirring were conducted for 6 hours at approximately 65° C. in an argon atmosphere. After cooling, reprecipitation was conducted using 500 ml of diethyl ether, the deposited polymer was filtered, and purification was conducted by reprecipitating again to obtain 17.91 g of the target polymer (84% yield). Weight-average molecular weight (Mw) by GPC analysis was 35800 (polystyrene equivalent), and dispersivity (Mw/Mn) was 3.72.

### Synthetic Example 4

Synthesis of a polymer containing 50 mol % of a structural unit (B-17 in Table 2) wherein R⁴ is a methyl group, and R⁵-R⁹ are hydrogen in general formula (2), and 50 mol % of a structural unit (B-1) wherein R⁴ is a hydrogen atom, R⁵ is an ethoxymethyl group, and R⁶-R⁹ are hydrogen atoms in general formula (2) (numerals assigned below to repeating units indicate mol %)

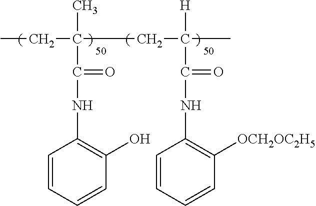

Polymerization was conducted in a manner identical to synthetic example 1, except that 13.25 g of N-(2-hydroxyphenyl)methacrylamide was used instead of N-(2-hydroxyphenyl)acrylamide, and 17.58 g of the target polymer was obtained (79% yield). Mw was 32100 (polystyrene equivalent), and Mw/Mn was 3.65.

### Synthetic Example 5

Synthesis of a polymer containing 30 mol % of a structural unit (B-16) wherein R⁴-R⁹ are hydrogen in general formula (2), 50 mol % of a structural unit (B-1) wherein R⁴ is a hydrogen atom, R⁵ is an ethoxymethyl group, and R⁶-R⁹ are hydrogen atoms in general formula (2), and 20 mol % of a structural unit (C-1 in Table 3) wherein R¹⁰ is a hydrogen atom, and R¹¹ is 2,6-norbornane lactone-5-yl group in general formula (3) (numerals assigned below to repeating units indicate mol %)

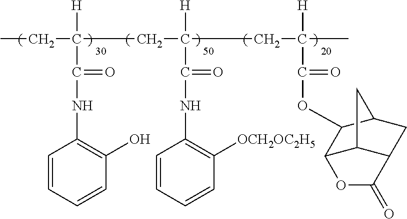

12.39 g of N-(2-hydroxyphenyl)acrylamide, 28 g of N-(2-ethoxymethoxyphenyl)acrylamide, and 10.54 g of 5-acroyloxy-2,6-norbornane lactone were dissolved in 119 ml of tetrahydrofuran. 0.416 g of 2,2′-azobis(isobutyronitrile) was added to that, and heating and stirring were conducted for 4 hours at approximately 65° C. in an argon atmosphere. After cooling, reprecipitation was conducted using 1000 ml of diethyl ether, the deposited polymer was filtered, and purification was conducted by reprecipitating again to obtain 48.79 g of the target polymer (96% yield). Mw was 29000 (polystyrene equivalent), and Mw/Mn was 3.32.

### Synthetic Example 6

Synthesis of a polymer which is 100 mol % of a structural unit (B-16) wherein R⁴-R⁹ are hydrogen atoms in general formula (2) (numerals assigned below to repeating units indicate mol %)

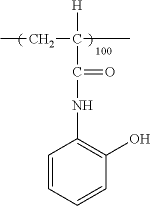

10 g of N-(2-hydroxyphenyl)acrylamide was dissolved in 30 ml of tetrahydrofuran. 0.201 g of 2,2′-azobis(isobutyronitrile) was added to that, and heating and stirring were conducted for 4 hours at approximately 65° C. in an argon atmosphere. After cooling, reprecipitation was conducted using 300 ml of diethyl ether, the deposited polymer was filtered, and purification was conducted by reprecipitating again to obtain 9.4 g of the target polymer (94% yield). Mw was 4900 (polystyrene equivalent), and Mw/Mn was 2.33.

### Synthetic Example 7

Synthesis of 2,2-bis(4-ethoxymethoxy-3-benzamide phenyl)hexafluoropropane (a compound wherein R¹² and R¹³ are ethoxymethyl groups, R¹⁴ and R¹⁵ are phenyl groups, and R¹⁶ is —C(CF₃)₂— in general formula (4), the following formula)

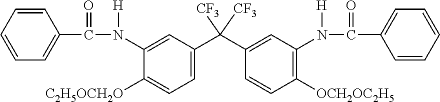

After dissolving 10 g of 2,2-bis(3-amino-4-hydroxyphenyl)hexafluoropropane in 60 ml of NMP, 2.546 g of lithium chloride was added, and the container including the mixture was stored in ice. 8.06 g of benzoyl chloride was added to this, and stirring was conducted for 1 hour under said cooling condition, and overnight at room temperature. The reaction mixture was poured into 600 ml of water, the precipitate that was deposited was filtered, and washed with water, whereby 12 g of 2,2-bis(4-hydroxy-3-benzamide phenyl)hexafluoropropane was obtained.

10 g of this 2,2-bis(4-hydroxy-3-benzamide phenyl)hexafluoropropane and 6.75 g of N,N-diisopropyl ethylamine were dissolved in 60 ml of NMP. Subsequently, 3.62 g of chloromethylethyl ether was added, and stirring was conducted for one entire day at room temperature. Thereafter, the reaction mixture was poured into 600 ml of water, and extracted with 300 ml of diethyl ether. The obtained diethyl ether layer was washed in the sequence of 0.06 N hydrochloric acid, saline solution, 3% aqueous sodium hydroxide, and saline solution. It was subsequently dried with magnesium sulfate, and the solvent was then removed by distillation under reduced pressure. The obtained residue was subjected to recrystallization with hexane/ethyl acetate (5/4) to obtain 7.8 g of the target substance (a white solid, 65% yield).

¹H-NMR (THF-d8, δ value): 1.22 (6H, t), 3.79 (4H, q), 5.39 (4H, s), 7.12 (2H, d), 7.27 (2H, d), 7.45-7.55 (6H, m), 7.9-7.93 (4H, m), 8.73 (2H, s), 8.84 (2H, s).

### Synthetic Example 8

Synthesis of N,N′-bis(2-ethoxymethoxy phenyl)isophthalamide (a compound wherein. R¹⁷ is a phenylene group, R¹⁸ and R¹⁹ are ethoxymethyl groups, and R²⁰ and R²¹ are hydrogen atoms in general formula (5), the following formula)

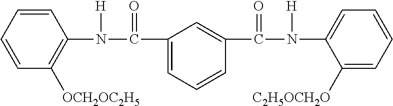

27.548 g of o-aminophenol and 11.484 g of lithium chloride were dissolved in 260 ml of NMP. 25 g of isophthaloyl chloride was added to this while the container including the mixture was stored in ice, and it was further stirred overnight at room temperature. Subsequently, the reaction mixture was poured into water, the precipitate that was deposited was filtered, and further washed with water. The obtained precipitate was again dissolved in 500 ml of tetrahydrofuran, and dried with magnesium sulfate, after which the solvent was removed by distillation under reduced pressure to obtain 40 g of N,N′-di(2-hydroxyphenyl)]isophthalamide.

Next, 40 g of N,N′-di(2-hydroxyphenyl)]isophthalamide and 44.52 g of N,N-diisopropylethyl amine were dissolved in 200 ml of NMP. 23.88 g of chloromethylethyl ether was added to this, and stirred for three days at room temperature. Subsequently, the reaction mixture was poured into 600 ml of water, and extracted with 300 ml of diethyl ether. The obtained diethyl ether layer was washed in the sequence of 0.06 N hydrochloric acid, saline solution, 3% aqueous sodium hydroxide, and saline solution. It was subsequently dried with magnesium sulfate, and the solvent was then removed by distillation under reduced pressure. The obtained residue was subjected twice to recrystallization with hexane/ethyl acetate (5/4) to obtain 26 g of the target substance (a white solid, 49% yield).

¹H-NMR (THF-d8, δ value): 1.21 (6H, t), 3.78 (4H, q), 5.35 (4H, s), 6.99-7.08 (4H, m), 7.24 (2H, dd), 7.64 (1H, s), 8.12 (2H, dd), 8.45 (2H, dd), 8.52 (1H, s), 9.00 (2H, brs).

### Example 1

A mixture of (a) 30 g of the polymer obtained by synthetic example 3, (b) 1.2 g of the amide derivative obtained by synthetic example 1, (c) 0.45 g of a photo-acid generator (N-(p-toluenesulfonyloxy)naphtalimide “NAI-101” (trade name; manufactured by Midori Kagaku Co., Ltd.), (d) 6 g of a dissolution inhibitor (the compound obtained by synthetic example 8), and (e) 49.7 g of γ-butyrolactone was filtered using a Teflon (registered trademark) filter of 0.2 μm to prepare a photosensitive resin composition of the chemical amplification type.

This photosensitive insulating resin composition was spin-coated onto a 5-inch silicon substrate, and was dried for 20 minutes at 110° C. in an oven to form a thin film of 11 μm thickness. Next, this was subjected to pattern exposure with ultraviolet rays (wavelength: 350-450 nm) via a photomask. After exposure, it was placed in an oven, and baked for 10 minutes at 100° C. Subsequently, developing was conducted at room temperature by the 2-minute immersion method in a 2.38% tetramethylammonium hydroxide (TMAH) aqueous solution, followed by rinsing treatment for 3 minutes with pure water. As a result, only the exposed portions of the photosensitive resin film were dissolved and removed by the developing solution, and a positive-type pattern was obtained. As a result of SEM observation of the obtained pattern, it was found that a through-hole pattern of 6 μm was resolved with a sensitivity of 600 mJ/cm².

Next, exposure was conducted over the entire surface of the wafer on which the pattern was formed with ultraviolet rays (wavelength: 350-450 nm) in an exposure amount of 600 mJ/cm². Baking was further conducted in an oven for 1 hour at 100° C. and for 1 hour at 220° C. in a nitrogen atmosphere, benzoxazole rings were formed, and a final pattern was obtained with a film thickness of 8 μm and excellent heat resistance and the like. As a result of SEM observation of the formed pattern, neither cracking nor peeling was observed in the pattern.

### Examples 2, 3

A photosensitive insulating resin composition was prepared in the same way as Example 1, except that the polymer obtained in synthetic example 4 or 5 was used instead of the polymer obtained in synthetic example 3. Spin coating, pattern sensitizing and the like were conducted, and a positive-type pattern was formed. The results of study of the pattern sensitivity and through-hole pattern resolution obtained at that time are shown in Table 4.

Next, the obtained pattern was baked in an oven for 1 hour at 100° C. and for 1 hour at 220° C. in a nitrogen atmosphere, benzoxazole rings were formed, and a final pattern was obtained with excellent heat resistance and the like. As a result of SEM observation of the formed pattern, neither cracking nor peeling was observed in the pattern in either case.

### Example 4

A photosensitive insulating resin composition of the chemical amplification type was prepared in the same way as Example 1, except that the amide derivative obtained in synthetic example 2 was used instead of the amide derivative obtained in synthetic example 1. Spin coating, pattern sensitizing and the like were conducted, and a positive-type pattern was formed. The results of study of pattern sensitivity and through-hole pattern resolution at that time are shown in Table 4.

Next, the obtained pattern was baked in an oven for 1 hour at 100° C. and for 1 hour at 220° C. in a nitrogen atmosphere, benzoxazole rings were formed, and a final pattern was obtained with excellent heat resistance and the like. As a result of SEM observation of the formed pattern, neither cracking nor peeling was observed in the pattern in any case.

### Example 5

A photosensitive insulating resin composition was prepared in the same way as Example 1, except that the dissolution inhibitor obtained in synthetic example 7 was used instead of the dissolution inhibitor obtained in synthetic example 8. Spin coating, pattern sensitizing and the like were conducted, and a positive-type pattern was formed. The results of study of pattern sensitivity and through-hole pattern resolution at that time are shown in Table 4.

Next, the obtained pattern was baked in an oven for 1 hour at 100° C. and for 1 hour at 220° C. in a nitrogen atmosphere, benzoxazole rings were formed, and a final pattern was obtained with excellent heat resistance and the like. As a result of SEM observation of the formed pattern, neither cracking nor peeling was observed in the pattern in any case.

TABLE 4

| | Photosensitive insulating resin composition | | | Pattern formation | | | |
|---|---|---|---|---|---|---|---|
| | | Amide derivative of | Dissolution | Resolution | Sensitivity | Final pattern | |
| | Polymer | general formula (1) | inhibitor | (μmφ) | (mJ/cm²) | Cracking | Peeling |
| Example 1 | Synthetic | Synthetic | Synthetic | 6 | 600 | None | None |
| | example 3 | example 1 | example 8 | | | | |
| Example 2 | Synthetic | Synthetic | Synthetic | 7 | 600 | None | None |
| | example 4 | example 1 | example 8 | | | | |
| Example 3 | Synthetic | Synthetic | Synthetic | 5 | 600 | None | None |
| | example 5 | example 1 | example 8 | | | | |
| Example 4 | Synthetic | Synthetic | Synthetic | 5 | 600 | None | None |
| | example 3 | example 2 | example 8 | | | | |
| Example 5 | Synthetic | Synthetic | Synthetic | 8 | 700 | None | None |
| | example 3 | example 2 | example 7 | | | | |

### Example 6

A mixture of (a) 10 g of the polymer obtained by synthetic example 5, (b) 0.4 g of the amide derivative obtained by synthetic example 2, (c) 0.15 g of a photo-acid generator (N-(p-toluenesulfonyloxy)naphtalimide “NAI-101” (trade name), (d) 2 g of a dissolution inhibitor (the compound obtained by synthetic example 8), and (e) 18 g of γ-butyrolactone was filtered using a Teflon (registered trademark) filter of 0.2 μm to prepare a photosensitive resin composition of the chemical amplification type.

This photosensitive insulating resin composition was spin coated onto a 5-inch silicon substrate with a film made of Cu, and dried for 20 minutes at 110° C. in an oven to form a thin film of 11 μm thickness. Next, pattern exposure was conducted with ultraviolet rays (wavelength: 350-450 nm) via a photomask. After exposure, it was baked in an oven for 10 minutes at 100° C., after which developing was conducted at room temperature by the 2-minute immersion method in a 2.38% TMAH aqueous solution, followed by rinsing treatment for 3 minutes with pure water. As a result, only the exposed portions of the photosensitive resin film were dissolved and removed by the developing solution, and a positive-type pattern was obtained. As a result of SEM observation of the obtained pattern, it was found that a through-hole pattern of 6 μm was resolved with a sensitivity of 600 mJ/cm².

Next, exposure was conducted over the entire surface of the wafer on which the pattern was formed with ultraviolet rays (wavelength: 350-450 nm) in an exposure amount of 600 mJ/cm². Baking was further conducted in an oven for 1 hour at 100° C. and for 1 hour at 220° C. in a nitrogen atmosphere, benzoxazole rings were formed, and a final pattern was obtained with a film thickness of 8 μm and excellent heat resistance and The like. As a result of SEM observation of the formed pattern, neither cracking nor peeling was observed in the pattern.

### Example 7

A mixture of (a) 10 g of the polymer obtained by synthetic example 6, (b) 0.4 g of the amide derivative obtained by synthetic example 2, (c) 0.15 g of a photo-acid generator (N-(p-toluenesulfonyloxy)naphtalimide “NAI-101” (trade name), (d) 3.5 g of a dissolution inhibitor (the compound obtained by synthetic example 8), and (e) 25 g of γ-butyrolactone was filtered using a Teflon (registered trademark) filter of 0.2 μm to prepare a photosensitive resin composition.

This photosensitive insulating resin composition was spin coated onto a 5-inch silicon substrate with a film made of Cu, and dried for 20 minutes at 110° C. in an oven to form a thin film of 11 μm thickness. Next, pattern exposure was conducted with ultraviolet rays (wavelength: 350-450 nm) via a photomask. After exposure, it was baked in an oven for 10 minutes at 100° C., after which developing was conducted at room temperature by the 2-minute immersion method in a 2.38% TMAH aqueous solution, followed by rinsing treatment for 3 minutes with pure water. As a result, only the exposed portions of the photosensitive resin film were dissolved and removed by the developing solution, and a positive-type pattern was obtained. As a result of SEM observation of the obtained pattern, it was found that a through-hole pattern of 10 μm was resolved with a sensitivity of 500 mJ/cm².

Next, exposure was conducted over the entire surface of the wafer on which the pattern was formed with ultraviolet rays (wavelength: 350-450 nm) in an exposure amount of 500 mJ/cm². Baking was further conducted in an oven for 1 hour at 100° C. and for 1 hour at 220° C. in a nitrogen atmosphere, benzoxazole rings were formed, and a final pattern was obtained with a film thickness of 8.2 μm and excellent heat resistance and the like. As a result of SEM observation of the formed pattern, neither cracking nor peeling was observed in the pattern.

### INDUSTRIAL APPLICABILITY

As is clear from the foregoing description, the photosensitive insulating resin composition of the present invention enables development with an aqueous alkali solution, has excellent resolution, also has excellent adhesion of the formed resin pattern to the substrate, and can be utilized in interlayer insulating film and surface protecting film and the like of semiconductor elements.

That is, a photosensitive insulating resin composition can be offered which has excellent film properties such as heat resistance, mechanical properties, and electrical properties, which enables alkali development, which obtains high resolution, and which has excellent substrate adhesion of the formed resin pattern.

1. A photosensitive insulating resin composition, comprising a polymer, a photosensitizer, and an amide derivative that is expressed by the following general formula (1). 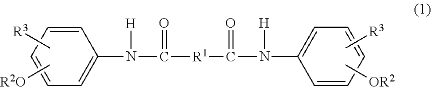
(In formula (1), R¹ represents a bivalent alkyl group, R² represents a hydrocarbon group with a carbon number of 1 to 10, and R³ represents a hydrogen atom or an alkyl group with a carbon number of 1 to 4.)

2. The photosensitive insulating resin composition according to claim 1, wherein said polymer is a polymer that contains one or more types of the repeating structural unit represented by the following general formula (2). 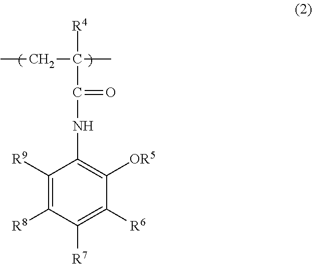
(In formula (2), R⁴ represents a hydrogen atom or a methyl group, R⁵ represents a hydrogen atom, or a group that is degraded by acid, and R⁶ to R⁹ each independently represent a hydrogen atom, a halogen atom, or an alkyl group with a carbon number of 1 to 4.)

3. The photosensitive insulating resin composition according to claim 2, wherein said polymer containing the repeating structural unit represented by general formula (2) additionally contains one or more types of the repeating structural unit represented by general formula (3). 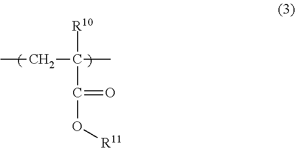
(In formula (3), R¹⁰ represents a hydrogen atom or a methyl group, and R¹¹ represents an organic group with a lactone structure.)

4. The photosensitive insulating resin composition according to claim 1, which additionally comprises a dissolution inhibitor.

5. The photosensitive insulating resin composition according to claim 4, wherein said dissolution inhibitor is a compound represented by the following general formula (4) or the following general formula (5). 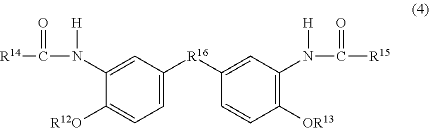
(In formula (4), R¹² and R¹³ represent groups that are degraded by acid, R¹⁴ and R¹⁵ represent straight-chain, branched or cyclic alkyl groups with a carbon number of 1 to 10, or aromatic hydrocarbon groups, and R¹⁶ represents a direct bond, —C(CF₃)₂—, —SO₂—, —CO—, —O— or bivalent hydrocarbon group.) 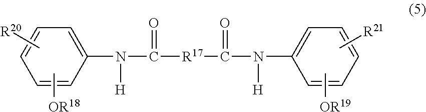
(In formula (5), R¹⁷ represents a bivalent hydrocarbon group, R¹⁸ and R¹⁹ represent groups that are degraded by acid, and R²⁰ and R²¹ represent hydrogen atoms, halogen atoms, or alkyl groups with a carbon number of 1 to 4.)

6. A pattern forming method, comprising the following steps:
a step in which the photosensitive resin composition according to claim 1 is coated onto a workpiece substrate, wherein the composition is a chemical amplification type composition;
a step in which prebaking of the composition is conducted;
a step in which exposure of the composition is conducted;
a step in which post-exposure baking of the composition is conducted;
a step in which developing of the composition is conducted;
and a step in which post-baking of the composition is conducted.

7. The pattern forming method according to claim 6, which additionally has a post-exposure step between the step in which developing is conducted and the step in which post-baking is conducted.

8. The pattern forming method according to claim 6, wherein, in the step in which developing is conducted, an aqueous alkali solution is used in development, and the exposed portions are dissolved by the aqueous alkali solution.

9. The pattern forming method according to claim 6, wherein exposure is conducted by actinic rays with a wavelength of 180-500 nm via a photomask.
